(19) United States
(12) Patent Application Publication
(10) Pub. No.: US 2024/0389439 A1
(43) Pub. Date: Nov. 21, 2024

(54) DISPLAY PANEL, DISPLAY DEVICE, AND VEHICLE-MOUNTED DISPLAY SYSTEM

(71) Applicant: BOE Technology Group Co., Ltd., Beijing (CN)

(72) Inventors: Qixiao WU, Beijing (CN); Xu LI, Beijing (CN); Cheng HAN, Beijing (CN); Hao GAO, Beijing (CN); Zhihui ZHANG, Beijing (CN); Weiye ZHENG, Beijing (CN)

(21) Appl. No.: 18/693,533

(22) PCT Filed: Jun. 6, 2023
(86) PCT No.: PCT/CN2023/098441

§ 371 Date: Mar. 20, 2024

(30) Foreign Application Priority Data
Jun. 21, 2022 (CN) 202210704394.3

(51) Int. Cl. H10K 59/80; H10K 59/38; H10K 59/40

(52) U.S. Cl. CPC H10K 59/879; H10K 59/38; H10K 59/40; H10K 59/8792

(57) ABSTRACT

A display panel comprises: a base substrate; a display function layer, comprising multiple light-emitting elements; a light-exit angle limiting layer, comprising a first light-blocking region and multiple first light-exit regions corresponding to multiple light-emitting elements on a one-to-one basis, an orthographic projection of each first light-exit region on the base substrate overlapping with an orthographic projection of a corresponding light-emitting element on the base substrate; a dimming function layer, comprising multiple dimming structures corresponding to multiple light-emitting elements on a one-to-one basis, an orthographic projection of each dimming structure on the base substrate not overlapping with an orthographic projection of a corresponding light-emitting element on the base substrate, the dimming structure being configured to change a direction of propagation of part of the light that is emitted by the corresponding light-emitting element and directed toward the first light-blocking region into a direction toward the corresponding first light-exit region.

### CROSS-REFERENCE TO RELATED APPLICATIONS

The present application is a U.S. National Phase Entry of International Application No. PCT/CN2023/098441 having an international filing date of Jun. 6, 2023, which claims priority to the Chinese Patent Application No. 202210704394.3, filed on Jun. 21, 2022, which are hereby incorporated herein by reference in their entireties.

### TECHNICAL FIELD

The present disclosure relates to the display field, in particular to a display panel, a display apparatus and a vehicle-mounted display system.

### BACKGROUND

Organic Light Emitting Diode (OLED) display apparatuses are a new kind of display apparatuses. Because of their advantages of self-luminescence, low driving voltage, high luminous efficiency, short response time, high definition and contrast, nearly 180° viewing angle, wide temperature range, flexible display and large area panchromatic display, they are considered as the most promising display apparatuses in the industry. The OLED display apparatuses are also increasingly applied in different fields.

### SUMMARY

In a first aspect, a display panel is provided in an embodiment of the present disclosure, which includes:
a base substrate;
a display functional layer, including a plurality of light emitting elements;
a light emitting angle definition layer, located on a side of the display functional layer away from the base substrate, and including a first light-shielding region, and a plurality of first light emitting regions corresponding to the plurality of light emitting elements in a one-to-one correspondence relationship, wherein an orthographic projection of a first light emitting region on the base substrate covers an orthographic projection of a corresponding light emitting element on the base substrate;
a light adjustment functional layer, located between the display functional layer and the light emitting angle definition layer, and including a plurality of light adjustment structures corresponding to the plurality of light emitting elements in a one-to-one correspondence relationship, wherein an orthographic projection of a light adjustment structure on the base substrate is not overlapped with an orthographic projection of a corresponding light emitting elements on the base substrate, and the light adjustment structure is configured to change a propagation direction of a part of light emitted by the corresponding light emitting element and directed towards the first light-shielding region into a direction directed towards a corresponding first light emitting region.

In some embodiments, the display panel further includes: an anti-crosstalk functional layer, located between the display functional layer and the light adjustment functional layer, and including a second light-shielding region, and a plurality of second light emitting regions corresponding to the plurality of light emitting elements in a one-to-one correspondence relationship, wherein an orthographic projection of a second light emitting region on the base substrate covers an orthographic projection of a corresponding first light emitting region on the base substrate, and the second light-shielding region is configured to shield light which is emitted by the corresponding light emitting element and directed towards first light emitting regions that are not the corresponding first light emitting region.

In some embodiments, a length of the light emitting element in a first direction is greater than a length of the same light emitting element in a second direction, both the first direction and the second direction are parallel to a plane where the base substrate is located, and the first direction intersects with the second direction; for any of the second light emitting regions, a length difference between the second light emitting region and the corresponding light emitting element in the first direction is greater than or equal to a length difference between the second light emitting region and the corresponding light emitting element in the second direction.

In some embodiments, for any of the second light emitting regions, the length difference between the second light emitting region and the corresponding light emitting element in the first direction ranges from 12 um to 24 um, and the length difference between the second light emitting region and the corresponding light emitting element in the second direction ranges from 12 um to 24 um.

In some embodiments, the display panel further includes a touch functional layer located on a side of the display functional layer away from the base substrate, wherein the touch functional layer includes a first metal layer, a touch insulating layer, and a second metal layer which are sequentially stacked along a direction away from the base substrate; the touch functional layer is located between the anti-crosstalk functional layer and the light adjustment functional layer; or, at least one of the first metal layer and the second metal layer within the touch functional layer is reused as the anti-crosstalk functional layer.

In some embodiments, the display panel further includes a color filter layer including a plurality of color filter patterns; the color filter layer is located between the anti-crosstalk functional layer and the light emitting angle definition layer; or, the color filter layer is located on a side of the light emitting angle definition layer away from the base substrate.

In some embodiments, a material of the anti-crosstalk functional layer includes a light absorbing material or a light reflecting material.

In some embodiments, a buffer layer is formed between the display functional layer and the anti-crosstalk functional layer; and/or, a buffer layer is formed between the anti-crosstalk functional layer and the light adjustment functional layer; and/or, a buffer layer is formed between the light adjustment functional layer and the light emitting angle definition layer.

In some embodiments, a length of a light emitting element in a first direction is greater than a length of the same light emitting element in a second direction, both the first direction and the second direction are parallel to a plane where the base substrate is located, and the first direction intersects with the second direction; for any of the first light emitting regions, a length difference between the first light emitting region and a corresponding light emitting element in the first direction is greater than or equal to a length difference between the first light emitting region and the corresponding light emitting element in the second direction.

The length difference ΔL of the first light emitting region and the corresponding light emitting element in the second direction satisfies the followings:

$$Δ L \leq 2 * {\sum }_{i = 1}^{j} ( {h}_{i} * tan {α}_{i} )$$

$$tan {α}_{i} = \frac{\frac{{n}_{1} * sin {α}_{1}}{{n}_{i}}}{\sqrt{1 - {( \frac{{n}_{1} * sin {α}_{1}}{{n}_{i}} )}^{2}}}$$

where j denotes a quantity of dielectric layers between a light emitting layer in the light emitting element and the light emitting angle definition layer, hᵢ denotes a thickness of an i-th dielectric layer located between the light emitting layer in the light emitting element and the light emitting angle definition layer and close to the light emitting layer, αᵢ denotes a propagation angle of light with a light emitting angle α₁, emitted by the light emitting layer in the light emitting element, when the light is incident on the i-th dielectric layer, α₁ is a preset angle constant and α₁≤20°.

In some embodiments, for any of the first light emitting regions, the length difference between the first light emitting region and the corresponding light emitting element in the first direction ranges from 6 um to 12 um, and the length difference between the first light emitting region and the corresponding light emitting element in the second direction ranges from 0 um to 12 um.

In some embodiments, the light adjustment structure includes at least one concave lens disposed above and on a periphery of the corresponding light emitting element.

In some embodiments, the light adjustment functional layer includes: a first refractive index dielectric layer, formed with a plurality of first openings corresponding to the plurality of light emitting elements in a one-to-one correspondence relationship, wherein a distance between a slope surface of the first refractive index dielectric layer surrounding the first opening and a normal line of the base substrate in a region where the first opening is located gradually increases in the direction away from the base substrate;
a second refractive index dielectric layer, located on a side of the first refractive index dielectric layer away from the base substrate, and covering the slope surface of the first refractive index dielectric layer;
wherein a refractive index of the first refractive index dielectric layer is smaller than a refractive index of the second refractive index dielectric layer; and
the light adjustment structure includes the slope surface.

In some embodiments, an orthographic projection of a bottom of a first opening on the base substrate covers an orthographic projection of a corresponding light emitting element on the base substrate; and the orthographic projection of the bottom of the first opening on the base substrate is located within a coverage region of an orthographic projection of a corresponding first light emitting region on the base substrate.

In some embodiments, a slope angle formed between the slope surface and a surface of the first refractive index dielectric layer on a side close to the base substrate is in a range of 50° to 75°.

In some embodiments, a difference between the refractive index of the second refractive index dielectric layer and the refractive index of the first refractive index dielectric layer is greater than or equal to 0.3.

In some embodiments, the display functional layer further includes an encapsulation layer; the encapsulation layer is located on a side of the light emitting elements away from the base substrate, and is configured to encapsulate the light emitting elements.

In some embodiments, a length of a light emitting element in a first direction is greater than or equal to 25 um; a length of the light emitting element in a second direction is less than or equal to 10 um; both the first direction and the second direction are parallel to the plane where the base substrate is located, and the first direction intersects with the second direction.

In some embodiments, a distance between the light emitting angle definition layer and the light emitting layer in the light emitting element in a normal direction of the base substrate is H, and H satisfies the following formula:

$$H \geq cot {α}^{*} \frac{L 2 + L {2}^{′}}{2}$$

where α is a preset light emitting angle constant and α≤20°, L2 is a length of the light emitting element in the second direction, and L2′ is a length of the first light emitting region corresponding to the light emitting element in the second direction.

In a second aspect, a display apparatus is also provided in an embodiment of the present disclosure, wherein the display apparatus includes the display panel according to the above-mentioned first aspect.

In a third aspect, a vehicle-mounted display system is also provided in an embodiment of the present disclosure, which includes the display apparatus according to the above-mentioned second aspect.

### BRIEF DESCRIPTION OF DRAWINGS

FIG. 1 illustrates schematically a cross-sectional view of a display panel in a vehicle-mounted display system involved in a related art.

FIG. 2 is a schematic diagram of a structure of an advance light control film in FIG. 1.

FIG. 3 illustrates schematically a cross-sectional view of a display panel according to an embodiment of the present disclosure.

FIG. 4 illustrates schematically another cross-sectional view of a display panel according to an embodiment of the present disclosure.

FIG. 5 illustrates schematically yet another cross-sectional view of a display panel according to an embodiment of the present disclosure.

FIG. 6 illustrates schematically a top view of a part of a first metal layer and a second metal layer in an embodiment of the present disclosure.

FIG. 7 illustrates schematically a cross-sectional view of the first metal layer and the second metal layer taken along an A-A′ direction in FIG. 6.

FIG. 8 illustrates schematically still yet another cross-sectional view of a display panel according to an embodiment of the present disclosure.

FIG. 9 illustrates schematically still yet another cross-sectional view of a display panel according to an embodiment of the present disclosure.

FIG. 10 illustrates schematically still yet another cross-sectional view of a display panel according to an embodiment of the present disclosure.

FIG. 11 is a schematic diagram of an optical path in a display panel according to an embodiment of the present disclosure.

FIG. 12 is a schematic diagram of a structure of a light adjustment functional layer according to an embodiment of the present disclosure.

FIG. 13 is a schematic diagram of another structure of a light adjustment functional layer according to an embodiment of the present disclosure.

FIG. 14 illustrates schematically a top view of a light emitting element, a first light emitting region and a second light emitting region which correspond to the light emitting element according to an embodiment of the present disclosure.

FIG. 15 illustrates schematically a cross-sectional view of a light emitting element, a first light emitting region, a second light emitting region and a light adjustment structure that correspond to the light emitting element according to an embodiment of the present disclosure.

FIG. 16 illustrates schematically a graph of a viewing angle luminance characteristic curve of a light emitting element in a first direction when it is simulated different functional layer structures are arranged according to an embodiment of the present disclosure.

FIG. 17 illustrates schematically a graph of a viewing angle luminance characteristic curve of a light emitting element in a second direction when it is simulated different functional layer structures are arranged according to an embodiment of the present disclosure.

### DETAILED DESCRIPTION

In order to make objectives, technical solutions and advantages of the present disclosure clearer, the technical solutions of the embodiments of the present disclosure will be clearly and completely described below with reference to the drawings of the embodiments of the present disclosure. Apparently, the described embodiments are a part of the embodiments of the present disclosure, not all of the embodiments. Based on the embodiments of the present disclosure, all other embodiments obtained by a person of ordinary skill in the art without paying any inventive effort are within the scope of protection of the present disclosure.

In an expression of a range from A to B in the present disclosure, a defined range includes two endpoint values A and B.

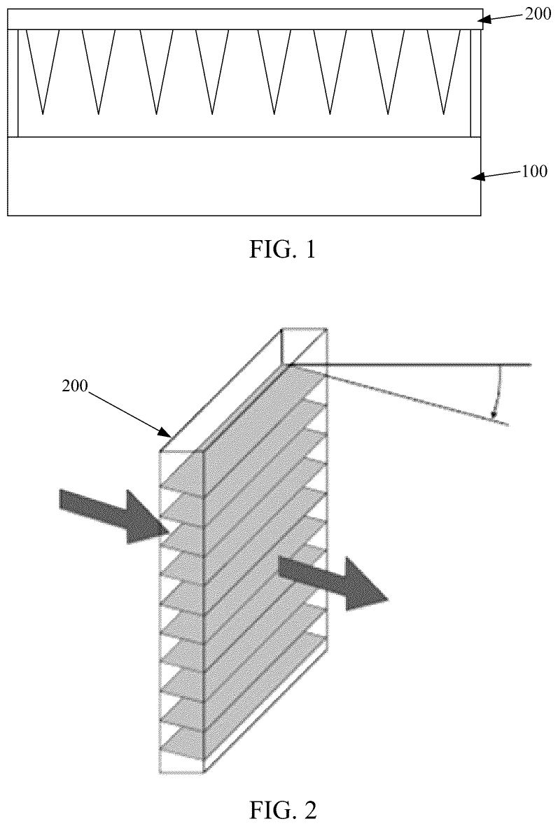

FIG. 1 illustrates schematically a cross-sectional view of a display panel in a vehicle-mounted display system related to a related art. FIG. 2 is a schematic diagram of a structure of an advance light control film in FIG. 1. As shown in FIGS. 1 and 2, in a vehicle-mounted display system involved in the related technology, a Liquid Crystal Display (LCD) is typically used as an instrument display or a central control display of an automobile. However, since a part of upward light emitted by an LCD 100 irradiates a windshield of an automobile, and is reflected by the windshield and then enters driver's eyes, the driver may see an LCD picture in front of the windshield, which affects a front line of sight of the driver. Especially in a process of driving at night, due to a dark external environment, the LCD picture in front of the windshield is more apparent, which seriously affects the front line of sight of the driver.

In order to effectively solve the problem that the light emitted from the LCD 100 reflects on the windshield and enters the driver's eyes, an Advance Light Control Film (ALCF) structure is provided on a light emitting side of the LCD 100 in a related art. At present, the ALCF structure 200 commercially available is a black resin having a cross section in a shape of a quasi-louver manufactured in a substrate with a high transmittance. The ALCF structure 200 can effectively shield light emitted from the LCD 100 and directed towards the windshield of the automobile, thereby effectively preventing the light emitted from the LCD 100 from being reflected on the windshield.

However, with development of the OLED, increasing manufacturers try to replace an LCD with an OLED display apparatus, and direct combination of the OLED display apparatus and the ALCF structure used in the LCD will lead to the following problems: luminance decay characteristics of the OLED combined with low transmittance (≤75%) of the ALCF structure makes the optical viewing angle characteristics of the product fail to meet the requirements of the majority of customers, and luminance of a narrow viewing angle needs to be further improved.

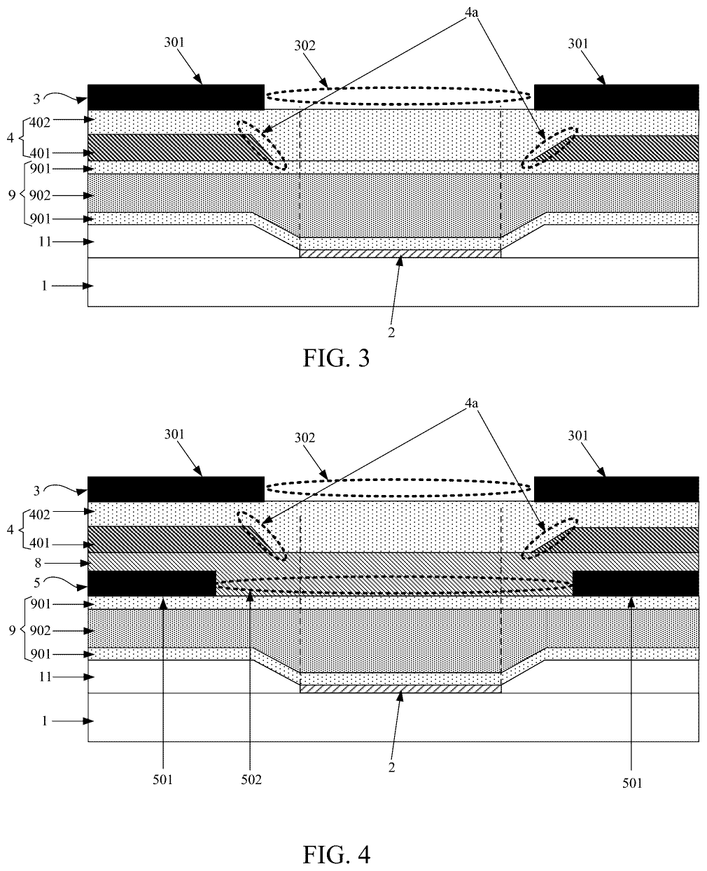

FIG. 3 illustrates schematically a cross-sectional view of a display panel according to an embodiment of the present disclosure. As shown in FIG. 3, the display panel includes a base substrate 1, a display functional layer, a light emitting angle definition layer 3, and a light adjustment functional layer 4.

The base substrate 1 may be a hard substrate (e.g. a glass substrate) or a flexible substrate (e.g. a resin substrate).

The display functional layer includes a plurality of light emitting elements 2 (only one light emitting element 2 is illustrated by example in the drawing). The light emitting element 2 may be a current-driven light emitting element 2 which generally includes an anode, a cathode, and a light emitting layer between the anode and the cathode. For convenience of description, an exemplary description is made by taking an OLED as the light emitting element 2 as an example.

It should be noted that, in an embodiment of the present disclosure, the display functional layer may further include a drive circuit layer (not shown) for driving the light emitting element 2 to emit light, the drive circuit layer includes a plurality of drive circuits (generally composed of a thin film transistor and a capacitor) corresponding to the light emitting elements 2 in a one-to-one correspondence relationship, and the drive circuits are configured to drive the corresponding light emitting elements 2 to emit light.

A pixel definition layer 11 is formed around the light emitting element 2, a pixel accommodation hole is formed in the pixel definition layer 11, and the light emitting element 2 is located in a corresponding pixel accommodation hole.

In addition, the display functional layer further includes an encapsulation layer 9 that is located on a side of the light emitting elements 2 away from the base substrate 1 and is configured to encapsulate the light emitting elements 2. Alternatively, the encapsulation layer may be of a stacked structure in which an organic sub-encapsulation layer 902 and an inorganic sub-encapsulation layer 901 are alternately arranged. In FIG. 3, a stacked structure of three sub-encapsulation layers in which two inorganic sub-encapsulation layers 901 sandwich with one organic sub-encapsulation layer 902 is exemplified. The stacked structure of three sub-encapsulation layers serves as an example only, and does not limit a technical solution of the present disclosure.

The light emitting angle definition layer 3 is located on a side of the display functional layer away from the base substrate 1. The light emitting angle definition layer 3 includes a first light-shielding region 301, and a plurality of first light emitting regions 302 corresponding to the light emitting elements 2 in a one-to-one correspondence relationship. An orthographic projection of a first light emitting regions 302 on the base substrate 1 covers an orthographic projection of a corresponding light emitting elements 2 on the base substrate 1.

When light irradiates the first light-shielding region 301 of the light emitting angle definition layer 3, the light cannot be emitted out. When light irradiates the first light emitting regions 302 of the light emitting angle definition layer 3, the light can be emitted out. By providing the light emitting angle definition layer 3, a resulting light emitting angle of the corresponding light emitting element 2 may be limited. When the product is applied to a vehicle-mounted display system, irradiation of wide-angle light on the windshield can be avoided effectively.

The resulting light emitting angle of the light emitting element 2 (achieving a narrow viewing angle) may be set in advance according to actual requirements. Then the resulting light emitting angle of the light emitting element 2 can be limited to a desired range by reasonably designing parameters such as a dimension of the light emitting element 2, a dimension of the corresponding first light emitting region 302, and a distance between the light emitting angle definition layer 3 and the light emitting element 2 in a normal direction of the base substrate 1.

In some embodiments, a material of the light emitting angle definition layer 3 includes a light absorbing material such as a black resin material. In this case, the first light emitting region 302 may be specifically a region where an opening on a light absorbing material film is located.

The light adjustment functional layer 4 is located between the display functional layer and the light emitting angle definition layer 3. The light adjustment functional layer 4 includes a plurality of light adjustment structures 4a corresponding to the plurality of light emitting elements 2. An orthographic projection of a light adjustment structure 4a on the base substrate 1 is not overlapped with an orthographic projection of a corresponding light emitting element 2 on the base substrate (the light adjustment structure 4a is located on a periphery of the corresponding light emitting element 2). The light adjustment structure 4a is configured to change a propagation direction of a part of light which is emitted from the corresponding light emitting element 2 and directed towards the first light-shielding region 301 into a direction directed towards a corresponding first light emitting region 302.

In the embodiment of the present disclosure, by providing the corresponding light adjustment structure 4a on the periphery of the light emitting element 2 (i.e., the orthographic projection of the light adjustment structure 4a on the base substrate 1 is outside the orthographic projection of the light emitting element 2 on the base substrate), the light adjustment structure 4a may adjust a propagation direction of a part of the light which originally be emitted towards the first light-shielding region 301 into a direction towards the corresponding first light emitting region 302, thereby increasing the quantity of light emitted through the first light emitting region 302, i.e., effectively improving the light emitting luminance of the first light emitting region 302, so as to achieve a purpose of improving luminance of the display panel in a narrow viewing angle.

FIG. 4 illustrates schematically another cross-sectional view of a display panel according to an embodiment of the present disclosure. As shown in FIG. 4, the display panel includes, not only the light emitting angle definition layer 3 and the light adjustment functional layer 4 in the previous embodiment, but also an anti-crosstalk functional layer 5.

The anti-crosstalk functional layer 5 is located between the display functional layer and the light adjustment functional layer 4. The anti-crosstalk functional layer 5 includes a second light-shielding region 501, and a plurality of second light emitting regions 502 corresponding to the light emitting elements 2 in a one-to-one correspondence relationship. An orthographic projection of the second light emitting region 502 on the base substrate 1 covers an orthographic projection of a corresponding first light emitting region 302 on the base substrate 1. The second light-shielding region 502 is configured to shield light which is emitted by the corresponding light emitting element 2 and directed towards first light emitting regions 302 that are not to the corresponding first light emitting region.

By providing the anti-crosstalk functional layer 5, light cross-talk between different pixels can be effectively avoided, which is beneficial to improving the display quality.

In some embodiments, a material of the anti-crosstalk functional layer 5 includes a light absorbing material such as a black resin material. In some other embodiments, the material of the anti-crosstalk functional layer 5 includes a light reflective material, such as a metal material having higher light reflectivity.

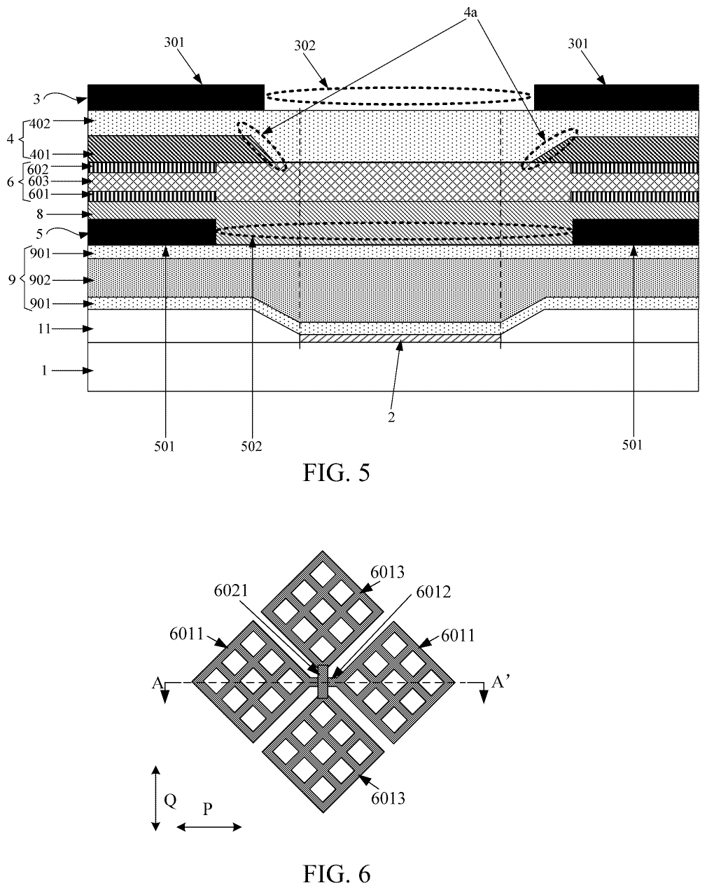

FIG. 5 illustrates schematically yet another cross-sectional view of a display panel according to an embodiment of the present disclosure. As shown in FIG. 5, the display panel further includes a touch functional layer 6 located on a side of the display functional layer away from the base substrate 1. The touch functional layer 6 includes a first metal layer 601, a touch insulating layer 603, and a second metal layer 602 which are stacked sequentially in a direction away from the base substrate 1. The display panel shown in FIG. 5 has not only a display function, but also a touch function.

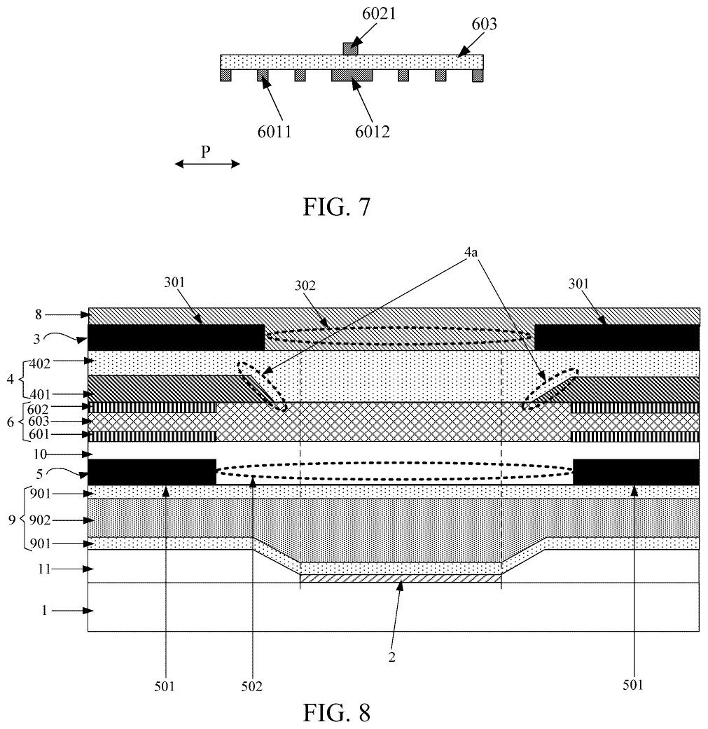

FIG. 6 illustrates schematically a top view of a part of a first metal layer 601 and a second metal layer 602 according to an embodiment of the present disclosure. FIG. 7 illustrates schematically a cross-sectional view taken along an A-A′ direction in FIG. 6. As shown in FIGS. 6 and 7, the first metal layer 601 and the second metal layer 602 are made of a metal material, and have a certain thickness having a light-shielding effect. The touch insulating layer 603 may be formed by a transparent organic insulating material (e.g. transparent resin) or a transparent inorganic insulating material (e.g. silicon oxide or silicon nitride), to ensure normal light emission of the light emitting element 2.

In some embodiments, the first metal layer 601 generally includes a plurality of second touch electrodes arranged along a third direction P (the second touch electrodes extend along the fourth direction Q) and a plurality of first touch electrodes arranged along a fourth direction Q (the first touch electrodes extend along the third direction P). It should be noted that only a part of a second touch electrode and a part of a first touch electrode are schematically depicted in FIG. 6 in a region where they intersect.

The first touch electrode includes a plurality of first touch sub-electrodes 6011 disposed along the third direction P, and a first connection electrode 6012 connected to two adjacent first touch sub-electrodes 6011 in the third direction P, and the second touch electrode includes a plurality of second touch sub-electrodes 6013 disposed along the fourth direction Q. A structure of the second metal layer 602 includes a second connection electrode 6021 connected to two adjacent second touch sub-electrodes 6013 in the fourth direction Q through a via on the touch insulating layer 603. In order to prevent the first touch sub-electrodes 6011 and the second touch sub-electrodes 6013 from shielding the light emitted from the light emitting element 2, the first touch sub-electrodes 6011 and the second touch sub-electrodes 6013 may be designed as grid-shaped electrodes and have a hollow structure in a region where the light emitting element 2 is located.

It should be noted that FIG. 7 only illustrates a case where the second connection electrode 6021 is located above the first touch sub-electrodes 6011 and the second touch sub-electrodes 6013. That is, the first touch sub-electrodes 6011 and the second touch sub-electrodes 6013 are located on the first metal layer 601, and the second connection electrodes 6021 are located on the second metal layer 602. In an embodiment of the present disclosure, the second connection electrode 6021 may also be located below the first touch sub-electrodes 6011 and the second touch sub-electrodes 6013. That is, the first touch sub-electrodes 6011 and the second touch sub-electrodes 6013 are located on the second metal layer 602, and the second connection electrodes 6021 are located on the first metal layer 601 (no corresponding figure is given for this case).

In addition, illustrations shown in FIGS. 6 and 7 in which shapes of the first touch sub-electrodes 6011 and the second touch sub-electrodes 6013 and the shape of one first touch sub-electrode 6011/second touch sub-electrode 6013 corresponding to nine hollow structures, only serve as an example, and do not limit the technical solution of the present disclosure.

As shown in FIG. 5, the touch functional layer 6 is located between the anti-crosstalk functional layer 5 and the light adjustment functional layer 4.

Referring to FIGS. 4 and 5, in some embodiments, the display panel further includes a color filter layer 8 including a plurality of color filter patterns. In an embodiment of the present disclosure, color display of the display panel can be achieved by providing the color filter layer 8. In the solutions shown in FIGS. 4 and 5, the color filter layer 8 is located between the anti-crosstalk functional layer 5 and the light emitting angle definition layer 3.

FIG. 8 illustrates schematically still yet another cross-sectional view of a display panel according to an embodiment of the present disclosure. As shown in FIG. 8, different from the color filter layer 8 located between the anti-crosstalk functional layer 5 and the light emitting angle definition layer 3 in the previous embodiment, the color filter layer 8 is located on a side of the light emitting angle definition layer 3 away from the base substrate 1.

In the solutions shown in FIGS. 4 and 5, since the color filter pattern in the color filter layer 8 is manufactured in the second light emitting region 502 of the anti-crosstalk functional layer 5 and above the anti-crosstalk functional layer 5, when a dimension of the second light emitting region 502 in the anti-crosstalk functional layer 5 is too large, film quality of the color filter pattern formed subsequently will be affected. Specifically, when the dimension of the second light emitting region 502 is too large, the color filter pattern formed in the second light emitting region 502 by an ink-jet printing process may have a thinner middle and thicker edges. Therefore, when the dimension of the second light emitting region 502 in the anti-crosstalk functional layer 5 is designed, not only the light cross-talk between different pixels needs to be considered, but also a restriction of a subsequent manufacturing process of the color filter pattern needs to be considered. Therefore, in practical applications, the dimension of the second light emitting region 502 is often arranged to be relatively small. Referring to FIG. 5, a distance between an edge of an orthographic projection of the second light emitting region 502 on the base substrate 1 and an edge of the orthographic projection of the corresponding light emitting element 2 on the base substrate 1 on a same side is generally about 6 um.

In the solution shown in FIG. 8, by moving the color filter layer 8 up to the side of the light emitting angle definition layer 3 away from the base substrate 1, only the light cross-talk between different pixels needs to be considered for dimension design of the second light emitting region 502, without considering the restriction of the subsequent manufacturing process of color filter pattern, so that the dimension of the second light emitting region 502 may be designed to be relatively large. Referring to FIG. 8, it is apparent the distance between the edge of the orthographic projection of the second light emitting region 502 on the base substrate 1 and the edge of the orthographic projection of the corresponding light emitting element 2 on the base substrate 1 on the same side may be greater than 6 um. For example, the distance may be set as 8 um, 10 um, and the like. Due to increased dimension of the second light emitting region 502, more light emitted from the light emitting element 2 can pass through the second light emitting region 502, which is beneficial to improving utilization rate of the light emitted from the light emitting element 2.

It should be noted that after the color filter layer 8 is moved up to the side of the light emitting angle definition layer 3 away from the base substrate 1, a planarization layer 10 needs to be provided on a side of the anti-crosstalk functional layer 5 away from the base substrate 1, so as to facilitate manufacturing a subsequent film structure.

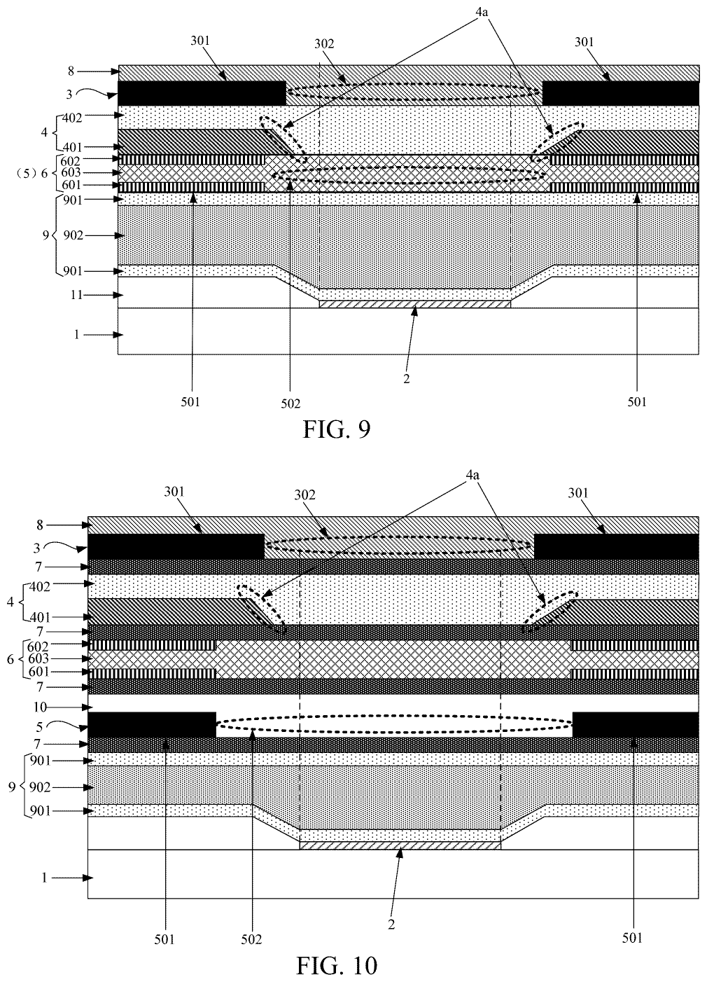

FIG. 9 illustrates schematically still yet another cross-sectional view of a display panel according to an embodiment of the present disclosure. As shown in FIG. 9, different from the touch functional layer 6 located between the anti-crosstalk functional layer 5 and the light adjustment functional layer 4 as shown in the previous embodiment, at least one of the first metal layer 601 and the second metal layer 602 within the touch functional layer 6 is reused as the anti-crosstalk functional layer 5.

That is, the first touch sub-electrode and the second touch sub-electrode can be reused as the anti-crosstalk functional layer 5. With this arrangement, a quantity of product generation processes can be effectively reduced, and production cost can be reduced.

In the display panel shown in FIG. 8, line widths of the first and second touch sub-electrodes are generally between 3 um and 5 um. In the display panel shown in FIG. 9, considering that the first touch sub-electrode and the second touch sub-electrode need to take into account the anti-crosstalk function, the line widths of the first touch sub-electrode and the second touch sub-electrode need to be appropriately increased. In some embodiments, the line widths of the first and second touch electrodes within the display panel shown in FIG. 9 may range from 7 um to 10 um.

When the anti-crosstalk functional layer 5 and the touch functional layer 6 in FIG. 8 are combined, a distance between the light emitting angle definition layer 3 and the light emitting element 2 in the normal direction of the base substrate 1 is reduced, and a maximum light emitting angle defined by the light emitting angle definition layer 3 and the first light emitting region 302 is increased. In order to ensure that the maximum light emitting angle defined by the light emitting angle definition layer 3 and the first light emitting region 302 is unchanged, a thickness of the film layer(s) between the light emitting angle definition layer 3 and the light emitting element 2 may be appropriately increased, such as by adjusting a thickness of the encapsulation layer 9, adjusting a thickness of the touch functional layer 6, adjusting a thickness of a buffer layer 7 (not shown in FIG. 8, which will be described in detail later), adjusting a thickness of the light emitting functional layer 4, etc., so as to ensure that the distance between the light emitting angle definition layer 3 and the light emitting element 2 in the normal direction of the base substrate 1 in FIG. 9 is equal to the distance between the light emitting angle definition layer 3 and the light emitting element 2 in the normal direction of the base substrate 1 in FIG. 8.

In addition, when the touch functional layer 6 and the anti-crosstalk functional layer 5 in FIG. 8 are combined, a distance between the touch functional layer 6 and the display functional layer is reduced, and obvious noise interference occurs between the display functional layer and the touch functional layer 6 (especially the touch signal noise in the touch functional layer 6 will obviously increase), which affects performance of the product. Therefore, in the process of appropriately increasing the thickness of the film layer(s) between the light emitting angle definition layer 3 and the light emitting element 2, the thickness of the encapsulation layer 9 is preferentially adjusted, so that the touch functional layer 6 and the display functional layer have a certain distance, thereby effectively reducing the noise interference between the touch functional layer 6 and the display functional layer.

In the process of increasing the thickness of the encapsulation layer 9, a thickness of the organic sub-encapsulation layer 902 is preferentially increased. In the solution shown in FIG. 8, the thickness of the organic sub-encapsulation layer 902 is about 6 um to 8 um. In the solution shown in FIG. 9, the organic sub-encapsulation layer 902 has a thickness of 10 um to 17 um.

FIG. 10 illustrates schematically still yet another cross-sectional view of a display panel according to an embodiment of the present disclosure. As shown in FIG. 10, in some embodiments, a buffer layer 7 may be optionally disposed between the display functional layer and the anti-crosstalk functional layer 5. A buffer layer 7 may also be optionally arranged between the anti-crosstalk functional layer 5 and the touch functional layer 6. A buffer layer 7 can also be optionally arranged between the touch functional layer 6 and the light adjustment functional layer 4. The buffer layer 7 may also be optionally provided between the light adjustment functional layer 4 and the light emitting angle definition layer 3.

By providing the buffer layer 7 between adjacent functional layer structures, film quality of a material film formed on a surface of the buffer layer 7 can be effectively improved, and bonding firmness between adjacent functional layer structures can be improved. A material of the buffer layer 7 may be an inorganic material such as silicon oxide and/or silicon nitride. The material of the buffer layer 7 may also be an organic material such as a resin material.

FIG. 11 is a schematic diagram of an optical path in a display panel according to an embodiment of the present disclosure. As shown in FIG. 11, light a emitted by a light emitting element 2 is shielded by a second light-shielding region 501 of an anti-crosstalk functional layer 5 (the anti-crosstalk functional layer 5 implements an anti-crosstalk function), light b emitted by the light emitting element 2 is irradiated to a light adjustment structure 4a through a corresponding second light emitting region 502 on the anti-crosstalk functional layer 5, and forms light b′ after light b is subjected to light adjustment function of light adjustment structure 4a, and the light b′ exits from a corresponding first light emitting region 302 on a light emitting angle definition layer 3 (a light adjustment functional layer 4 implements a light adjustment function and improves light emitting luminance of the first light emitting region 302), light c emitted by the light emitting element 2 is irradiated to a first light-shielding region 301 on the light emitting angle definition layer 3 through the corresponding second light emitting region 502 on the anti-crosstalk functional layer 5, and light d emitted by the light emitting element 2 is irradiated to the first light emitting region 302 on the light emitting angle definition layer 3 through the corresponding second light emitting region 502 on the anti-crosstalk functional layer 5 (the light emitting angle definition layer 3 implements definition on a light emitting angle).

A specific structure of the light adjustment functional layer 4 in the embodiment of the present disclosure will be described as an example below only.

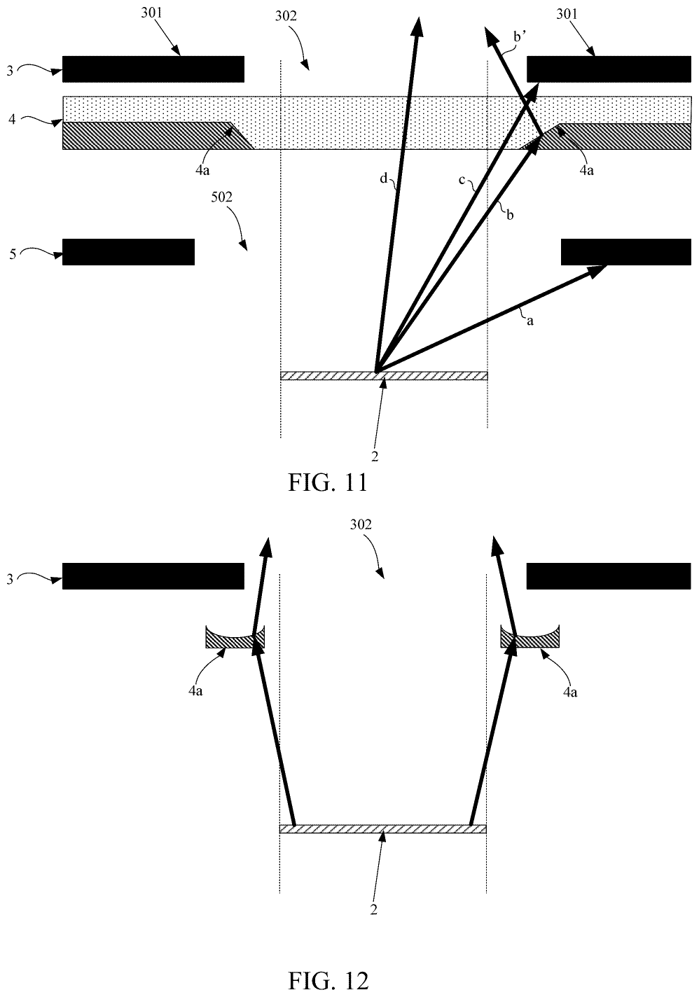

FIG. 12 is a schematic diagram of a structure of a light adjustment functional layer according to an embodiment of the present disclosure. As shown in FIG. 12, in some embodiments, a light adjustment structure 4a in a light adjustment functional layer 4 includes a concave lens. Specifically, at least one concave lens may be provided on a periphery of a light emitting element 2. For example, a plurality of concave lenses may be provided around a region where the light emitting element 2 is located. Since the concave lens has a function of diverging light, a part of light which originally is directed towards a first light-shielding region 301 forms divergent light when reaching the concave lens, and a part of the divergent light is emitted out through a corresponding first light emitting region 302. In an embodiment, a plurality of concave lenses are provided at uniform intervals around a region where a corresponding light emitting element 2 is located.

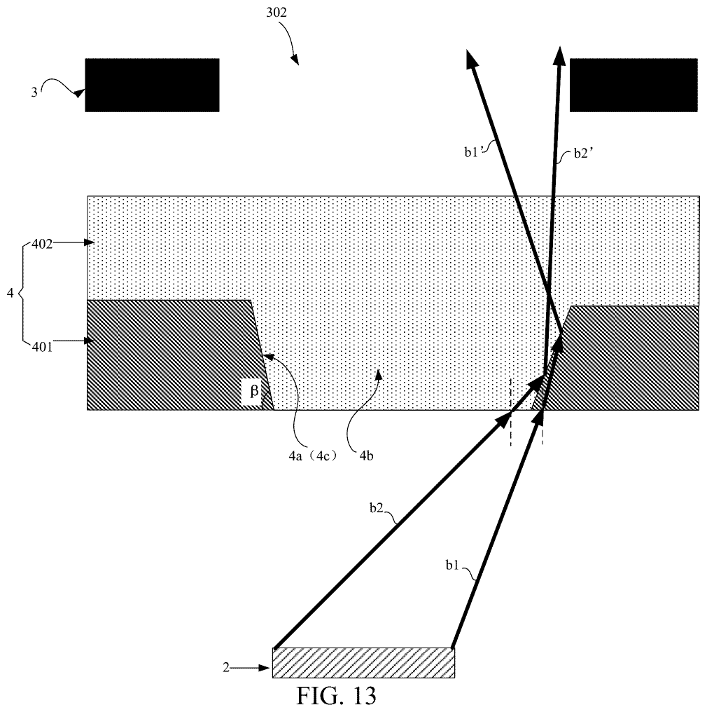

FIG. 13 is a schematic diagram of another structure of a light adjustment functional layer according to an embodiment of the present disclosure. As shown in FIG. 13, in some embodiments, a light adjustment functional layer 4 includes a first refractive index dielectric layer 401 and a second refractive index dielectric layer 402 which are stacked.

A plurality of first openings 4b corresponding to light emitting elements 2 in a one-to-one correspondence relationship are formed on the first refractive index dielectric layer 401, and a distance between a slope surface 4c of the first refractive index dielectric layer 401 surrounding the first opening 4b and a normal direction of a base substrate 1 in a region where the first opening is located gradually increases in a direction of an orthographic projection of a surface on a side of the first refractive index dielectric layer 401 close to the base substrate 1, away from the opening. That is, the distance between the slope surface of the first refractive index dielectric layer surrounding the first opening and the normal line of the base substrate in a region where the first opening is located gradually increases in the direction away from the base substrate. In other words, an acute angle is formed between the slope surface 4c and the surface of the first refractive index dielectric layer 401 on the side close to the base substrate 1.

The second refractive index dielectric layer 402 is located on a side of the first refractive index dielectric layer 401 away from the base substrate 1, and covers the slope surface 4c on the first refractive index dielectric layer 401. A refractive index of the first refractive index dielectric layer 401 is smaller than a refractive index of the second refractive index dielectric layer 402.

In this case, the slope surface 4c has a light adjustment function and may be used as a light adjustment structure 4a.

Subsequently referring to FIG. 13, when light b1 reaches a lower surface of the slope surface 4c, the light b1 is refracted towards a direction close to the normal direction of the slope surface 4c because an optically denser medium is above the slope surface 4c and an optically sparser medium is below the slope surface 4c, a refracted light b1′ is formed. In this case, a shape and a dimension of a first light emitting region 302 in the light emitting angle definition layer 3 may be designed accordingly to ensure that the refracted light b1′ can pass through the first light emitting region 302.

After light b2 reaches an upper surface of a film, since media with different refractive indices are on two sides of the slope surface 4c, at least part of the light b2 is reflected to form reflected light b2′. Of course, in some specific conditions, the light b2 satisfies a total reflection condition, and total reflection may occur on the slope surface 4c to form the reflected light b2′. In this case, the shape and dimension of the first light emitting region 302 on the light emitting angle definition layer 3 may be correspondingly designed to ensure that the reflected light b2′ can pass through the first light emitting region 302.

In some embodiments, an orthographic projection of a bottom of the first opening 4b on the base substrate 1 covers an orthographic projection of a corresponding light emitting element 2 on the base substrate 1. The orthographic projection of the bottom of the first opening 4b on the base substrate 1 is located within a coverage region of an orthographic projection of a corresponding first light emitting region 302 on the base substrate 1. That is, an area of the orthographic projection of the bottom of the first opening 4b on the base substrate 1 is larger than or equal to an area of the orthographic projection of the corresponding light emitting element 2 on the base substrate 1, and the area of the orthographic projection of the bottom of the first opening 4b on the base substrate 1 is smaller than or equal to an area of the orthographic projection of the corresponding first light emitting region 302 on the base substrate 1. With this design, the light emitted from the light emitting element 2 and irradiated to the slope surface 4c can be emitted out from the corresponding first light emitting region 302 as much as possible after being refracted or reflected on the slope surface 4c, which is beneficial to improving light emitting luminance of the first light emitting region 302.

In some embodiments, a slope angle β formed between the slope surface 4c and the side surface of the first refractive index dielectric layer 401 close to the base substrate 1 ranges from 50° to 75°.

In some embodiments, a difference between the refractive index of the second refractive index dielectric layer 402 and the refractive index of the first refractive index dielectric layer 401 is greater than or equal to 0.3.

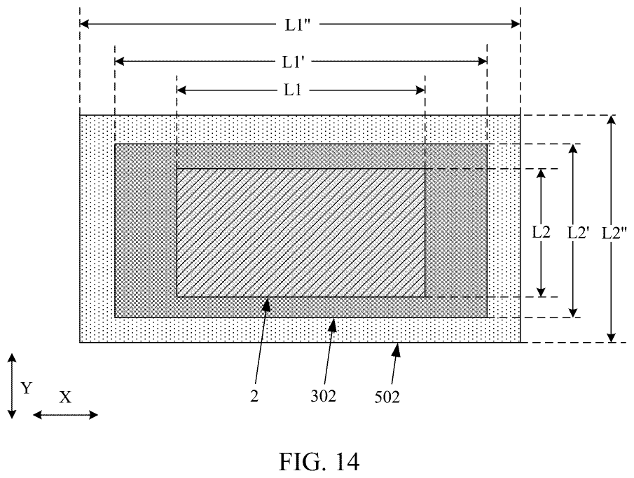

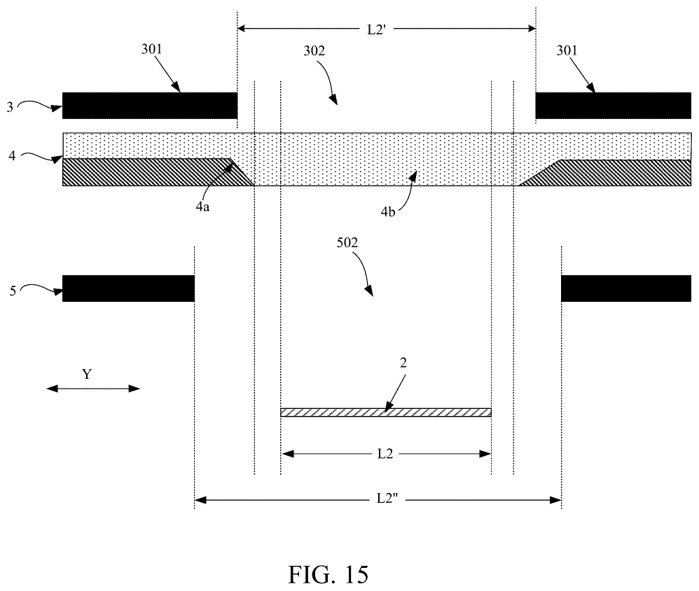

FIG. 14 illustrates schematically a top view of a light emitting element 2, a first light emitting region 302 and a second light emitting region 502 which correspond to the light emitting element 2 according to an embodiment of the present disclosure. FIG. 15 illustrates schematically a cross-sectional view of a light emitting element 2, a first light emitting region 302, a second light emitting region 502 and a light adjustment structure 4a which correspond to the light emitting element 2 in this embodiment. As shown in FIGS. 14 and 15, a display panel provided in the embodiment of the present disclosure may be applied to a vehicle-mounted display system. For the vehicle-mounted display system, in order to prevent light from irradiating a windshield and causing interference to a front line of sight of a driver, a light emitting angle of the display panel in a vertical direction is generally strictly restricted, while a light emitting angle of the display panel in a horizontal direction is not restricted.

Based on consideration of applying the display panel to the vehicle-mounted display system, in the embodiment of the present disclosure, a length of the light emitting element 2 in a first direction X is greater than a length of the same light emitting element 2 in a second direction Y. Both the first direction X and the second direction Y are parallel to a plane where the base substrate 1 is located, and the first direction X intersects with the second direction Y.

In the embodiment of the present disclosure, the longer the length of the light emitting element 2 in a direction, the smaller an influence of the light emitting angle definition layer 3, the light adjustment functional layer 4 and the anti-crosstalk functional layer 5 on overall regulation of the light emitting element 2 in that direction, and vice versa, the shorter the length of the light emitting element 2 in a direction, the greater the influence of the light emitting angle definition layer 3, the light adjustment functional layer 4, and the anti-crosstalk functional layer 5 on the overall regulation of the light emitting element 2 in that direction.

Based on the case where the vehicle-mounted display system has a relatively strict restriction on the light emitting angle of the display panel in the vertical direction and has no restriction on the light emitting angle of the display panel in the horizontal direction, in an embodiment of the present disclosure, the length L1 of the light emitting element 2 in the first direction X (the first direction X is the horizontal direction in application) may be set relatively long, and the length L2 of the light emitting element 2 in the second direction Y (the second direction Y is the vertical direction in application) may be set relatively short.

In some embodiments, the length L1 of the light emitting element 2 in the first direction X is greater than or equal to 25 um, in this case the light emitting angle definition layer 3, the light adjustment functional layer 4 and the anti-crosstalk functional layer 5 have relatively little influence on the overall regulation of the light emitting element 2 in the first direction X. The length L2 of the light emitting element 2 in the second direction Y is less than or equal to 10 um, and the light emitting angle definition layer 3, the light adjustment functional layer 4 and the anti-crosstalk functional layer 5 have relatively great influence on the overall regulation of the light emitting element 2 in the first direction X. As an alternative implementation, an orthographic projection of the light emitting element 2 on the base substrate 1 is rectangular.

In addition, considering that the greater the difference between a length of the first light emitting region 302 on the light emitting angle definition layer 3 and a length of the corresponding light emitting element 2 in a direction, the greater a restriction of the first light emitting region 302 on the light emitting element 2 in that direction (the smaller a maximum light emitting angle), then, in an embodiment of the present disclosure, for any first light emitting region 302, a length difference L1′−L1 between a length of the first light emitting region 302 and a length of the corresponding light emitting element 2 in the first direction X is greater than or equal to a length difference L2′−L2 between a length of the first light emitting region 302 and a length of the corresponding light emitting element 2 in the second direction Y. With the arrangement, a regulation influence of the light emitting angle definition layer 3 on the light emitting element 2 in the first direction X is greater than or equal to a regulation influence on the light emitting element 2 in the second direction Y.

In some embodiments, the length difference ΔL between the length of the first light emitting region 302 and the length of the corresponding light emitting element 2 in the second direction satisfies the followings:

$$Δ L \leq 2 * {\sum }_{i = 1}^{j} ( {h}_{i} * tan {α}_{i} )$$

$$tan {α}_{i} = \frac{\frac{{n}_{1} * sin {α}_{1}}{{n}_{i}}}{\sqrt{1 - {( \frac{{n}_{1} * sin {α}_{1}}{{n}_{i}} )}^{2}}}$$

Where j denotes a quantity of dielectric layers between a light emitting layer in the light emitting element 2 and the light emitting angle definition layer, h; denotes a thickness of an i-th dielectric layer between the light emitting layer in the light emitting element 2 and the light emitting angle definition layer and close to the light emitting layer, αᵢ denotes a propagation angle of light with a light emitting angle of α₁, emitted by the light emitting layer in the light emitting element 2, when the light is incident on the i-th dielectric layer, and α₁ is a preset definition angle constant and α₁≤20°.

That is, in virtue of the above design, light with an emitting angle greater than or equal to α₁, emitted by the light emitting layer cannot be emitted from the corresponding first light emitting region finally. That is, the light emitted from the first light emitting region must be light which is emitted from the light emitting layer and has a light emitting angle less than 20°.

It should be noted that in this embodiment of the present disclosure, the light emitting angle or the propagation angle of the light refers to an included angle between the light and the normal line of the base substrate.

In some embodiments, for any first light emitting region 302, the length difference L1′−L1 between the first light emitting region 302 and the corresponding light emitting element 2 in the first direction X ranges from 6 um to 12 um, and the length difference L2′−L2 between the first light emitting region 302 and the corresponding light emitting element 2 in the second direction Y ranges from 0 um to 12 um.

Similarly, the greater a difference between a length of the second light emitting region 502 in the anti-crosstalk functional layer 5 and a length of the corresponding light emitting element 2 in a direction, the greater a restriction of the second light emitting region 502 on the light emitting element 2 in that direction (the smaller the maximum light emitting angle). Therefore, in an embodiment of the present disclosure, for any second light emitting region 502, a length difference L1″−L1 between a length of the second light emitting region 502 and the length of the corresponding light emitting element 2 in the first direction X is greater than or equal to a length difference L2″−L2 between a length of the second light emitting region 502 and the length of the corresponding light emitting element 2 in the second direction Y. With this arrangement, a regulation influence of the anti-crosstalk functional layer 5 on the light emitting element 2 in the first direction X is greater than or equal to the regulation influence on the light emitting element 2 in the second direction Y.

In some embodiments, for any second light emitting region 502, the length difference L1″−L1 between the second light emitting region 502 and the corresponding light emitting element 2 in the first direction X ranges from 12 um to 24 um, and the length difference L2″−L2 between the second light emitting region 502 and the corresponding light emitting element 2 in the second direction Y ranges from 12 um to 24 um.

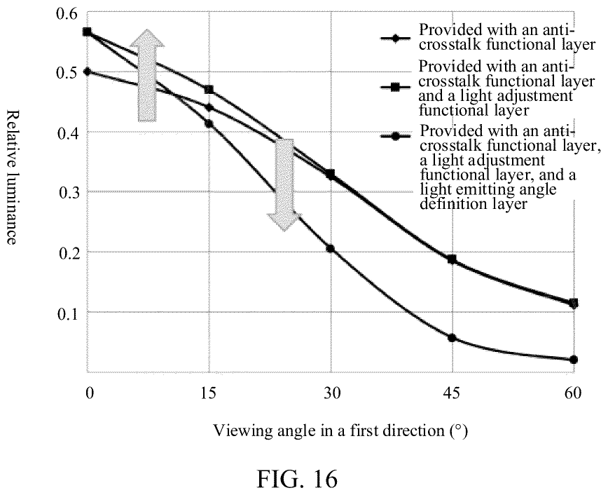

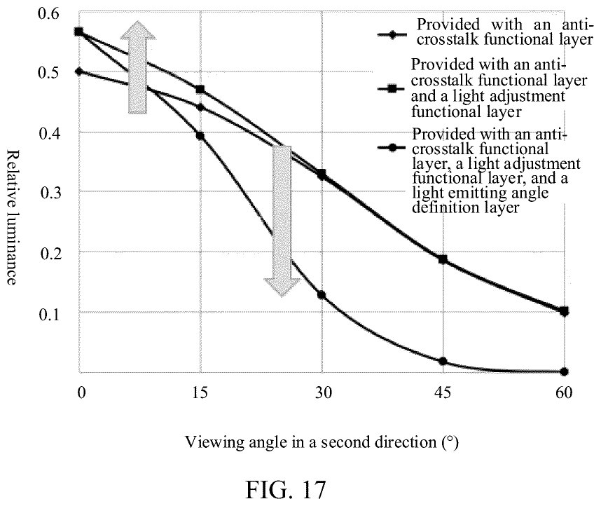

FIG. 16 illustrates schematically a graph of a viewing angle luminance characteristic curve of a light emitting element in a first direction when it is simulated that different functional layer structures are arranged according to an embodiment of the present disclosure. FIG. 17 illustrates schematically a graph of a viewing angle luminance characteristic curve of a light emitting element in a second direction when it is simulated that different functional layer structures are arranged according to an embodiment of the present disclosure. As can be seen from FIGS. 16 and 17, when a light adjustment functional layer 4 is provided, either in the first direction X or in the second direction Y, light emitting luminance of the light emitting element 2 at a small angle (0° to 10°) is improved; and when the light emitting angle definition layer 3 is provided, the light emitting luminance at a large angle (more than or equal to 15°) can be effectively restricted.

In addition, the light emitting angle definition layer 3, the light adjustment functional layer 4, and the anti-crosstalk functional layer 5 have a greater effect on an overall regulation of the light emitting element 2 in the second direction Y than on an overall regulation of the light emitting element 2 in the first direction X. For example, as shown in FIGS. 16 and 17, relative luminance of the light emitting element 2 at an angle of 20° in the first direction X is about 0.35, and relative luminance at an angle of 20° in the second direction Y is about 0.3, relative luminance of the light emitting element 2 at an angle of 30° in the first direction X is about 0.2, and relative luminance at an angle of 30° in the second direction Y is about 0.13; relative luminance of the light emitting element 2 at an angle of 40° in the first direction X is about 0.1, and relative luminance at an angle of 40° in the second direction Y is about 0.04.

Based on the same inventive concept, a display apparatus is also provided in an embodiment of the present disclosure, which includes a display panel, wherein the display panel employs the display panel provided in the aforementioned embodiments. The display apparatus may be any product or component with a display function, such as a mobile phone, a tablet computer, a television, a display, a laptop computer, a digital photo frame, and a navigator.

Based on the same inventive concept, a vehicle-mounted display system is also provided in an embodiment of the present disclosure. The vehicle-mounted display system includes a display apparatus that employs the display apparatus provided in the previous embodiment, and may be used as an instrument display or a central control display of an automobile.

It may be understood that the above implementations are only exemplary implementations employed for the purpose of illustrating the principles of the present disclosure, however the present disclosure is not limited thereto. To those of ordinary skills in the art, various modifications and improvements may be made without departing from the essence and substance of the present disclosure, and these modifications and improvements are also considered to be within the scope of the present disclosure.

1. A display panel, comprising:
a base substrate;
a display functional layer, comprising a plurality of light emitting elements;
a light emitting angle definition layer, located on a side of the display functional layer away from the base substrate, and comprising a first light-shielding region, and a plurality of first light emitting regions corresponding to the plurality of light emitting elements in a one-to-one correspondence relationship, wherein an orthographic projection of a first light emitting region on the base substrate covers an orthographic projection of a corresponding light emitting element on the base substrate;
a light adjustment functional layer, located between the display functional layer and the light emitting angle definition layer, and comprising a plurality of light adjustment structures corresponding to the plurality of light emitting elements in a one-to-one correspondence relationship, wherein an orthographic projection of a light adjustment structure on the base substrate is not overlapped with an orthographic projection of a corresponding light emitting element on the base substrate, and the light adjustment structure is configured to change a propagation direction of a part of light which is emitted by the corresponding light emitting element and directed towards the first light-shielding region into a direction directed towards a corresponding first light emitting region.

2. The display panel of claim 1, further comprising:
an anti-crosstalk functional layer, located between the display functional layer and the light adjustment functional layer, and comprising a second light-shielding region, and a plurality of second light emitting regions corresponding to the plurality of light emitting elements in a one-to-one correspondence relationship, wherein an orthographic projection of a second light emitting region on the base substrate covers an orthographic projection of a corresponding first light emitting region on the base substrate, and the second light-shielding region is configured to shield light which is emitted by the corresponding light emitting element and directed towards first light emitting regions that are not the corresponding first light emitting region.

3. The display panel of claim 2, wherein a length of the light emitting element in a first direction is greater than a length of the same light emitting element in a second direction, both the first direction and the second direction are parallel to a plane where the base substrate is located, and the first direction intersects with the second direction;
for any of the second light emitting regions, a length difference between the second light emitting region and the corresponding light emitting element in the first direction is greater than or equal to a length difference between the second light emitting region and the corresponding light emitting element in the second direction.

4. The display panel of claim 3, wherein for any of the second light emitting regions, the length difference between the second light emitting region and the corresponding light emitting element in the first direction ranges from 12 um to 24 um, and the length difference between the second light emitting region and the corresponding light emitting element in the second direction ranges from 12 um to 24 um.

5. The display panel of claim 2, further comprising a touch functional layer located on a side of the display functional layer away from the base substrate, wherein the touch functional layer comprises a first metal layer, a touch insulating layer, and a second metal layer which are sequentially stacked along a direction away from the base substrate;
the touch functional layer is located between the anti-crosstalk functional layer and the light adjustment functional layer; or, at least one of the first metal layer and the second metal layer within the touch functional layer is reused as the anti-crosstalk functional layer.

6. The display panel of claim 2, further comprising a color filter layer comprising a plurality of color filter patterns;
the color filter layer is located between the anti-crosstalk functional layer and the light emitting angle definition layer;
or, the color filter layer is located on a side of the light emitting angle definition layer away from the base substrate.

7. The display panel of claim 2, wherein a material of the anti-crosstalk functional layer comprises a light absorbing material or a light reflecting material.

8. The display panel of claim 2, wherein a buffer layer is formed between the display functional layer and the anti-crosstalk functional layer;
and/or, a buffer layer is formed between the anti-crosstalk functional layer and the light adjustment functional layer;
and/or, a buffer layer is formed between the light adjustment functional layer and the light emitting angle definition layer.

9. The display panel of claim 1, wherein a length of a light emitting element in a first direction is greater than a length of the same light emitting element in a second direction, both the first direction and the second direction are parallel to a plane where the base substrate is located, and the first direction intersects with the second direction;
for any of the first light emitting regions, a length difference between the first light emitting region and a corresponding light emitting element in the first direction is greater than or equal to a length difference between the first light emitting region and the corresponding light emitting element in the second direction.

10. The display panel of claim 9, wherein the length difference ΔL of the first light emitting region and the corresponding light emitting element in the second direction satisfies the followings:
$$Δ L \leq 2 * {\sum }_{i = 1}^{j} ( {h}_{i} * tan {α}_{i} )$$
$$tan {α}_{i} = \frac{\frac{{n}_{1} * sin {α}_{1}}{{n}_{i}}}{\sqrt{1 - {( \frac{{n}_{1} * sin {α}_{1}}{{n}_{i}} )}^{2}}}$$
where j denotes a quantity of dielectric layers between a light emitting layer in the light emitting element and the light emitting angle definition layer, hᵢ denotes a thickness of an i-th dielectric layer located between the light emitting layer in the light emitting element and the light emitting angle definition layer and close to the light emitting layer, αᵢ denotes a propagation angle of light with a light emitting angle α₁, emitted by the light emitting layer in the light emitting element, when the light is incident on the i-th dielectric layer, αᵢ is a preset angle constant and α₁20°.

11. The display panel of claim 9, wherein for any of the first light emitting regions, the length difference between the first light emitting region and the corresponding light emitting element in the first direction ranges from 6 um to 12 um, and the length difference between the first light emitting region and the corresponding light emitting element in the second direction ranges from 0 um to 12 um.

12. The display panel of claim 1, wherein the light adjustment structure comprises at least one concave lens disposed above and on a periphery of the corresponding light emitting element.

13. The display panel of claim 1, wherein the light adjustment functional layer comprises:
a first refractive index dielectric layer, formed with a plurality of first openings corresponding to the plurality of light emitting elements in a one-to-one correspondence relationship, wherein a distance between a slope surface of the first refractive index dielectric layer surrounding the first opening and a normal line of the base substrate in a region where the first opening is located gradually increases in the direction away from the base substrate;
a second refractive index dielectric layer, located on a side of the first refractive index dielectric layer away from the base substrate and covering the slope surface of the first refractive index dielectric layer;
wherein a refractive index of the first refractive index dielectric layer is smaller than a refractive index of the second refractive index dielectric layer; and
the light adjustment structure comprises the slope surface.

14. The display panel of claim 13, wherein an orthographic projection of a bottom of a first opening on the base substrate covers an orthographic projection of a corresponding light emitting element on the base substrate; and
the orthographic projection of the bottom of the first opening on the base substrate is located within a coverage region of an orthographic projection of a corresponding first light emitting region on the base substrate.

15. The display panel of claim 13, wherein a slope angle formed between the slope surface and a side surface of the first refractive index dielectric layer close to the base substrate is in a range of 50° to 75°.

16. The display panel of claim 13, wherein a difference between the refractive index of the second refractive index dielectric layer and the refractive index of the first refractive index dielectric layer is greater than or equal to 0.3.

17. The display panel of claim 1, wherein the display functional layer further comprises an encapsulation layer;
the encapsulation layer is located on a side of the light emitting elements away from the base substrate, and is configured to encapsulate the light emitting elements.

18. The display panel of claim 1, wherein a length of a light emitting element in a first direction is greater than or equal to 25 um;
a length of the light emitting element in a second direction is less than or equal to 10 um;
both the first direction and the second direction are parallel to the plane where the base substrate is located, and the first direction intersects with the second direction.

19. A display apparatus, comprising the display panel according to claim 1.

20. A vehicle-mounted display system, comprising the display apparatus of claim 19.
